(19) United States
(12) Patent Application Publication
(10) Pub. No.: US 2026/0331868 A1
(43) Pub. Date: Oct. 22, 2026

(54) SYSTEMS AND METHODS FOR DRIVING A LIGHT EMITTER

(71) Applicant: OWiC Technologies Inc., Ithaca, NY (US)

(72) Inventors: Alyosha Molnar, Ithaca, NY (US); Alejandro J. Cortese, Ithaca, NY (US); Paul L. McEuen, Ithaca, NY (US); Kevin Sun, Ithaca, NY (US)

(73) Assignee: OWiC Technologies Inc., Ithaca, NY (US)

(21) Appl. No.: 19/565,343

(22) Filed: Mar. 12, 2026

Related U.S. Application Data
(63) Continuation of application No. PCT/US2024/045791, filed on Sep. 9, 2024.
(60) Provisional application No. 63/582,756, filed on Sep. 14, 2023.

(51) Int. Cl. H01S 5/042; H01S 5/183

(52) U.S. Cl. CPC H01S 5/0428; H01S 5/183

(57) ABSTRACT

An optical tag circuit includes a storage element configured to store electric energy, a power source configured to generate electric current and provide the electric current to the storage element for storage as electric energy, and a regulation module configured to determine a level of stored electric energy and compare the level to a threshold electric energy corresponding to a predetermined current threshold of the light emitter. When the level is determined to be greater than or equal to the threshold electric energy and information is to be transmitted by the circuit, the electric energy stored in the storage element is provided to the light emitter in a pulse, and when the level is below the threshold electric energy, the stored electric energy is restricted from reaching the light emitter. A peak power of the pulse is greater than an average power available from the power source.

### CROSS-REFERENCE TO RELATED APPLICATIONS

This application is a continuation of International Patent Application No. PCT/US2024/045791, filed Sep. 9, 2024, entitled “SYSTEMS AND METHODS FOR DRIVING A LIGHT EMITTER,” which claims the benefit of and priority to U.S. Provisional Patent Application No. 63/582,756, filed Sep. 14, 2023, entitled “SYSTEMS AND METHODS FOR DRIVING A LIGHT EMITTER” the entire disclosures of which are hereby incorporated by reference, for all purposes, as if fully set forth herein.

### BACKGROUND OF THE INVENTION

There is a growing interest and need for linking digital content and sensor information to the physical world. As examples, QR codes and data matrices using information encoded spatially are used in laboratories across the globe to link patient data to small vials, in grocery stores to link dietary information to packaged food and beverages, and in homes to launch applications from installation instructions in product packaging. The information extracted from these links is often read out with electronic devices equipped with a camera such as a smartphone or standalone electronic reader.

There is additionally a growth of the Internet of Things (IOT) to extract sensor and identification information from physical objects such as temperature, humidity, or pressure and digitally link that information to the objects. This is often accomplished with RF-powered or battery-powered electronic sensors or identification tags on an object that communicate out information with RF signals that are received by an electronic device. Methods and devices for linking such digital content and sensor information to physical objects in increasingly smaller form factors are widely desired. This desire can be motivated by the size of the object being too small for current link devices or by aesthetic considerations where an object's appearance may be altered significantly by the presence of a large link technology.

Light emitters such as Light Emitting Diodes (LEDs) have been increasingly utilized in the field of optical communication due to their high efficiency, relatively low cost, and design flexibility. Laser diodes have been helpful in enabling high-speed data transmission over fiber-optic networks, transforming applications such as data center interconnects, telecommunications, and consumer electronics.

LEDs, with their incoherent and broad spectral emission, are well suited for shorter-range applications such as local area networks or plastic optical fiber communication. These light emitting technologies have helped address the ever-growing global bandwidth demand, while providing the groundwork for emerging communication applications and lidar systems. Typically, these applications operate with many milliwatts or watts of power consumption, have a minimum constant threshold current running through the light elements during operation, and operate at high bandwidths in the gigabits per second range for rapid communication.

### SUMMARY OF THE INVENTION

The present disclosure relates generally to optically powered, light-pulse generating circuits. More particularly, the present disclosure relates to systems and methods for regulating power to one or more components of an optical tag circuit to provide improved efficiency for a light emitter based on power conservation criteria.

There exists a need for reduced size, optical tag circuits operating at maximum efficiencies for driving light emitters for optical tag circuits under limited power conditions (e.g., optical tag circuits powered by incident light). Embodiments consistent with the present disclosure provide an optically powered electronic circuit to drive a light emitter at low power. The circuit includes a storage element configured to store electric energy, a power source configured to generate electric current and provide the electric current to the storage element for storage as electric energy, and a regulation module configured to determine a level of electric energy stored in the storage element and compare the level of electric energy to a threshold electric energy corresponding to a predetermined current threshold of the light emitter. The regulation module is configured such that when the level is determined to be greater than or equal to the threshold electric energy and information is to be transmitted by the circuit, the electric energy stored in the storage element is provided to the light emitter in a pulse, and when the level falls below the threshold electric energy, the electric energy stored in the storage element is restricted from reaching the light emitter. A peak power of the pulse is greater than an average power available from the power source.

The storage element may include at least one capacitor configured to provide electric energy.

The power source may be configured to transduce incident light to generate the electric current.

The power source may include a plurality of photovoltaic cells connected in series and configured to provide electric current in proportion to the amount of incident light collected by the plurality of photovoltaic cells.

The power source may include a plurality of photovoltaic cells connected in parallel and configured to provide electric energy in proportion to the amount of incident light collected by the plurality of photovoltaic cells.

The circuit may further include a pulse generator configured to generate the pulse, wherein the regulation module is linked with the pulse generator and configured to cause the pulse generator to terminate the pulse when the level of electric energy is determined to be below the threshold electric energy, and a switch in communicative connection with the pulse generator, the switch being configured to open when the regulation module causes termination of the pulse.

The circuit may further include a pulse generator, wherein the pulse generator is configured to pause between pulses for a predetermined duration, the predetermined duration being selected so as to allow the electric energy stored in the storage element to reach an upper energy threshold, based on the electric current provided by the power source.

The circuit may further include a pulse generator configured to generate the pulse, the pulse having a pulse duration shorter than a discharge duration of the storage element when discharging the electric energy at the predetermined current threshold of the light emitter.

The circuit may have a length, X, and a width, Y, and a surface area, X*Y, wherein the surface area is less than 0.09 mm².

The peak power may be 1000 times greater than the average power.

The peak power may be 10000 times greater than the average power.

The storage element may include a battery.

An average of a standby electric current between the pulse and a second pulse following the pulse may be less than 10⁻⁶ Amperes. For example, the pulse may range between 10⁻⁹ and 10⁻⁷ Amperes.

The average power available from the power source may be less than 10⁻⁶ Watts.

The light emitter may include a vertical-cavity surface emitting laser (VCSEL) and the average power drawn from the storage element to provide the electric energy to the light emitter is less than 10⁻⁷ Watts.

The regulation module may be configured to enable the VCSEL to emit light based on a voltage across the VCSEL.

An average current through the light emitter when the level is determined to be below the threshold electric energy may be less than 1 microamp.

A circuit average power corresponding to the power consumed by the circuit may be less than 1 microwatt.

A pulse duration of the pulse may be fixed based on predetermined data.

The light emitter may be configured to draw electric energy from the storage element as an electric current of less than or equal to 0.7 milliamperes while emitting light at or above the predetermined current threshold.

According to further embodiments of the present disclosure, a method for driving a vertical-cavity surface-emitting laser (VCSEL) is provided. The method includes storing electric energy from a photovoltaic cell in a storage device, and providing a pulse, by a pulse generator, to cause the storage device to provide stored electric energy to the VCSEL during the pulse. The electric energy is provided by the storage device at a predetermined current threshold of the VCSEL, the predetermined current threshold corresponding to a current at which an efficiency of the VCSEL in emitting light is greater than or equal to a predetermined efficiency.

The circuit may use an average power of less than 10⁻⁶ Watts, and the peak power of the VCSEL pulse is higher than 10⁻³ Watts.

The power source may be configured to receive electric energy and reach the threshold current level in less than 0.1 seconds.

The pulse generator may be further configured to provide the pulse after receiving a command from a regulation module based on a voltage across the VCSEL.

The light emitter comprises a vertical-cavity surface emitting laser (VCSEL) and an average power drawn from the storage device to provide the stored electric energy to the VCSEL is less than 10⁻⁷ Watts.

According to still further embodiments of the present disclosure, a circuit for driving a light emitter for an adaptable duration is provided. The circuit includes a power source configured to store and provide electric energy, a power monitor configured to monitor an available energy from the power source, and a pulse generator configured to generate a pulse for a pulse duration based on the available energy. The pulse duration is determined such that a pulse energy for the pulse duration remains below the available energy throughout the pulse duration, and wherein the pulse energy is configured to cause the light emitter to produce light at a predetermined intensity for each pulse.

The power source may include one or more photovoltaic cells configured to collect incident light, and the pulse duration is based on the amount of incident light collected by the one or more photovoltaic cells.

The pulse duration may directly correlate to the average power corresponding to the electric energy available from the power source.

According to still further embodiments of the present disclosure, a circuit for driving a light emitter with a current source is provided. The circuit includes a power source configured to store and provide electric energy, wherein the electric energy stored in the power source over a duration corresponds to an available average power, a pulse generator configured to generate a pulse for a pulse period, the pulse period being determined based on a peak power of the pulse, the peak power being greater than the available average power, and the pulse period being less than the duration, a current source element configured to provide a steady current from the power source to the light emitter during the pulse period, wherein the current source element has an operational voltage threshold corresponding to a lower emitter threshold for the light emitter, and a comparison module configured to determine a voltage across the current source and compare the voltage to the operational voltage threshold. When the voltage is greater than or equal to the operational voltage threshold, the pulse continues and when the voltage is lower than the operational voltage threshold, the pulse generator is configured to terminate the pulse.

The comparison module may include a comparator configured to compare the voltage across the current source to the operational voltage threshold.

The comparator may include a CMOS inverter configured with one or more transistors connected in series, wherein the operational voltage threshold is determined based on the quantity of the one or more transistors of the CMOS inverter.

The current source may be configured as a current mirror used to provide a fixed electric current through the light emitter.

The comparison module may be configured to operate an SR latch used to control a switch configured to allow or restrict the electric energy from reaching the light emitter.

The current mirror may be configured to connect to a switch in series and the comparison module is configured to use the switch to terminate electric current from reaching the light emitter when the voltage across the current source is lower than the operational voltage threshold.

The comparison module may include a comparator connected to a set-reset latch and logic gates configured to initiate the pulse by a rising edge of a control input voltage, and terminate the pulse when the voltage across the current source is less than the operational voltage threshold.

According to yet further embodiments of the present disclosure, a circuit for driving a light emitter with a voltage offset is provided. The circuit includes a power source configured to store and provide electric energy at a power voltage, a voltage bias element configured to provide a bias voltage in series with the power voltage, and a comparison circuit configured to compare the voltage from the voltage bias element to the voltage corresponding to a light emitter voltage threshold. The comparison circuit is further configured to enable the power source to provide the electric energy to the light emitter in a pulse for a pulse period based on a peak power of the pulse, the peak power being greater than an available average power corresponding to the energy stored in the power source over a duration greater than the pulse period, when the voltage from the voltage bias element is greater than or equal to the light emitter voltage threshold, and the comparison circuit is further configured to restrict the power source from providing the electric energy to the light emitter, when the voltage from the voltage bias element is less than the light emitter voltage threshold.

The comparison circuit may include a comparator comprising a CMOS inverter configured with one or more transistors connected in series, wherein the bias voltage is determined based on the quantity of the one or more transistors in the CMOS inverter.

The bias voltage may correspond to a light emitter threshold voltage corresponding to a minimum voltage for the light emitter to emit light, and over which the brightness of the light emitted from the light emitter begins to rise monotonically.

The light emitter may include a vertical-cavity surface-emitting laser (VCSEL).

The comparison circuit may be configured to operate a set-reset latch used to control a switch configured to allow or restrict the electric energy from reaching the light emitter.

The power source may include one or more photovoltaic cells configured to receive incident light, and the bias voltage is adjustable based on the brightness of incident light, wherein the bias voltage is adjusted to be inversely proportional to the brightness of incident light.

The bias voltage may be adjustable based on the average power corresponding to the electric energy available from the power source.

The comparison circuit may be further configured to restrict the energy supply module from providing the electric energy by communicating with a switch configured to operate in response to the pulse.

The comparison circuit may include a comparator connected to an SR latch and one or more logic gates configured to operate with a pulse by a rising edge of a control input voltage, and terminate the pulse when the electric energy from the voltage bias element is less than the light emitter voltage.

Importantly, any of the features recited above and described herein may be used in combination with any of the other features, except where otherwise contradictory, without departing from the scope of the present disclosure.

The foregoing general description and the following detailed description are exemplary and explanatory only and are not restrictive of the claims.

### BRIEF DESCRIPTION OF THE DRAWINGS

The accompanying drawings, which are incorporated in and constitute a part of this

FIG. 1 is a graphical representation showing typical features of the opto-electronic operation of a semiconductor light emitter consistent with the disclosed embodiments;

FIG. 2A is a schematic diagram of an illustrative optically powered light emitter circuit consistent with the disclosed embodiments.

FIG. 2B is a flowchart highlighting an illustrative method for operating an optically powered light emitter circuit.

FIGS. 3A-C are graphical representations showing voltage and current and light emission in various combinations in a light pulse generator according to embodiments. FIG. 3A shows the voltage across the storage element, discharging during each pulse to close to V_{TO}, and recharging between pulses. FIG. 3B shows the current through the light emitter. FIG. 3C shows the light emitted by the light emitter.

FIG. 4 is a graph of normalized output light/pulse vs incident light for an optically powered light emitter circuit according to embodiments.

FIG. 5 is a graphical representation of output light/pulse vs incident light from an optical tag circuit for three different fixed pulse widths consistent with the disclosed embodiments.

FIG. 6 is a schematic diagram of an illustrative optical tag circuit consistent with the disclosed embodiments.

FIG. 7 is a schematic diagram of another illustrative optically tag circuit consistent with the disclosed embodiments.

FIG. 8 is a graphical representation of output light/pulse vs incident light from an optical tag circuit operating with four different fixed currents consistent with the disclosed embodiments.

FIG. 9 is a schematic diagram of another illustrative optically powered light emitter circuit consistent with the disclosed embodiments

FIG. 10 is a schematic diagram of another illustrative optically powered light emitter circuit consistent with the disclosed embodiments.

FIGS. 11A-C are graphical representations showing voltage, current and light emission in various combinations in an optically powered light emitter circuit consistent with the disclosed embodiments. FIG. 11A shows the capacitor voltage as a function of time. FIG. 11B shows the light emitter current as a function of time. FIG. 11C shows the output light intensity as a function of time.

FIG. 12 is a graphical representation of output light/pulse vs incident light from an optical tag circuit operating with a voltage floor consistent with the disclosed embodiments.

FIG. 13 is an illustrative physical layout of an optical tag circuit consistent with the disclosed embodiments.

### DETAILED DESCRIPTION OF SPECIFIC EMBODIMENTS

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions or modifications may be made to the components illustrated in the drawings, and the illustrative methods described herein may be modified by substituting, reordering, removing, or adding steps to the disclosed methods. Accordingly, the following detailed description is not limited to the disclosed embodiments and examples. Instead, the proper scope is defined by the appended claims.

### Optical Tag Circuit Overview

The present disclosure is directed to systems and methods enabling efficient light emission from an optical tag circuit with the goal of providing information via an encoded optical signal. Embodiments of the present disclosure can be implemented to construct devices that enable power control for optical tag circuits used for encoding and emitting information via an encoded optical signal (e.g., via light emissions). The disclosed embodiments enable optical tag circuits whose size is near to or smaller than the spatial resolution of a camera used to capture an encoded optical signal. Optical tag circuits incorporating embodiments of the present disclosure can therefore be used to tag objects without significantly altering an appearance of the object. For example, a fully integrated circuit according to embodiments of the present disclosure may have length and width dimensions less than or equal to approximately 0.15 mm, 0.2 mm, 0.3 mm, 0.4 mm, 0.5 mm, or even 0.75 mm, and any value in between for example, 0.47 mm. According to some embodiments, a circuit may have square dimensions of 0.3 mm by 0.3 mm, with a surface area of a projection of the optical tag circuit<=0.09 mm², though square shape is not intended to be limiting and the optical tag circuits of the present disclosure may have any desired shape, e.g., rectangle, rhomboid, etc. As used herein the length and width dimensions refer to an outer edge of a hypothetical envelope surrounding the optical tag circuit 114 at its maximum along a corresponding outer edge of the package comprising the circuit

In power-constrained communication systems in which communication is slow (<100 Kbps) and/or in which the average power available is as low as the sub microwatt range, such as, for example, where power is being harvested from the environment, using systems and methods disclosed herein, optical communication can provide reasonable performance for wireless digital communication. Disclosed embodiments thus relate to electronic circuits for driving a light emitting element efficiently at low power by minimizing the operation of the light emitting element under conditions that may not efficiently produce light. As used herein, the term “low power” refers to an average power consumption of less than or equal to about 100 nano Watts (nW). The disclosed embodiments are therefore directed to driving a light emitter efficiently enough to cause lasing under low power conditions.

As used throughout this disclosure, the term “optical tag circuit” refers to a device capable of being mounted on, in, or near an object and configured to provide information to a device external to the optical tag circuit. A “light emitter” refers to any device configured to output light in response to being provided with electrical energy.

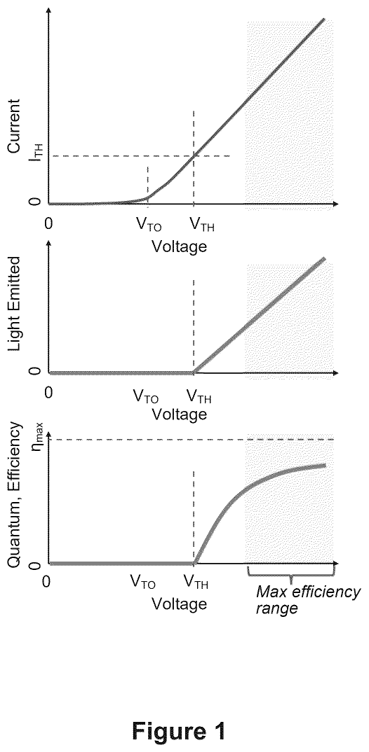

FIGS. 1A-C are graphical representations showing typical features of a semiconductor light emitter consistent with the disclosed embodiments. A semiconductor light emitter may include, for example, a vertical-cavity surface-emitting lasers (“VCSEL,”) a light emitting diode (“LED,”) a micro light emitting diode (“microLED”,) a resonant-cavity light-emitting diode (“RCLED”), etc. FIG. 1A shows an example current (I) voltage (V) curve where current is close to zero for a voltage less than VTO, and then rising monotonically for voltages greater than VTO.

FIG. 1B shows a graph of light output intensity vs input voltage for a semiconductor light emitter. According to the graph, emitted light is close to zero until current is greater than ITH, with voltage greater than VTH, after which light rises monotonically with current and voltage.

FIG. 1C shows a graph of quantum efficiency (i.e., number of photons emitted per second)/(number of electrons flowing per second)) versus voltage across the semiconductor light emitter. As shown, efficiency rises from zero as current and voltage increase beyond ITH and VTH, but starts to saturate at higher currents, such that there is a range of voltage where efficiency is close to its maximum.

As can be understood from FIGS. 1A-1C, light emitting diodes (LEDs) and, especially, VCSELs transduce electrical current into light more efficiently at higher current density, such that the same amount of electrical charge will produce more photons if delivered with a higher instantaneous current for a shorter time. Laser diodes in particular will generate little or no light when driven by a current less than some threshold level. Above this level, light emission increases approximately proportionally to the excess current above this threshold. More generally, there will be a range of electrical currents where reasonably efficient transduction of electrons to photons occurs, and below that range, efficiency degrades significantly.

Certain parameters of a light emitter as described herein can be defined as: 1) a turn on voltage of the light emitter (VTO), below which little current flows therethrough; 2) a threshold current (ITH) and associated threshold voltage (VTH), the threshold voltage being greater than the turn on voltage, but below which little light is emitted, and 3) a current range with associated voltages where the light emitter transduces electric energy to light with near maximum efficiency. For most LEDs and VCSELs, current can be considered to rise approximately linearly with voltage above VTO due, for example, to the intrinsic resistance of the element.

When an average power available in a circuit driving an LED or a VCSEL is less than what is needed to generate current in the efficient range of that transducer, then a pulsed form of communication may be desirable for ensuring high efficiency operation. In this context, electrical energy (e.g., energy derived from incident light) can be stored over time, and then may be released through a light emitter for a shorter period of time, but with a higher magnitude. Such a pulse's amplitude may increase inversely with the duty cycle of the pulses used, such that as more time passes between pulses, more energy is thereby accumulated and those pulses become brighter.

As described herein, this approach can be generalized and extended to situations where an available average power or current is orders of magnitude less than the amount of power or current needed to generate efficient light pulses.

### Pulse Driven Switching

According to embodiments of the present disclosure an optical tag circuit may include a light emitter, a power source, an energy storage element, and circuitry, including, for example, a regulation element, to briefly, in a controlled way, connect the storage element to the light emitter so as to generate pulses of light, by discharging the storage element when a light pulse is desired, such as when communicating a “1” in a simple digital communication system.

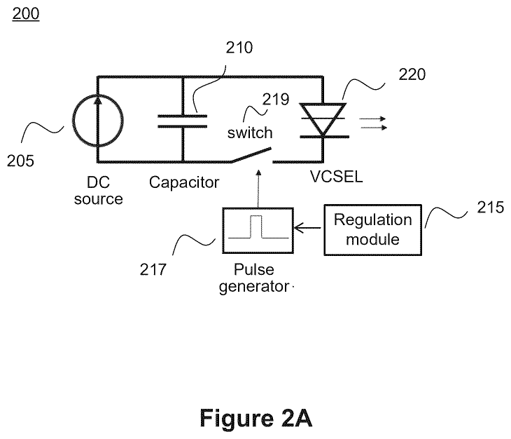

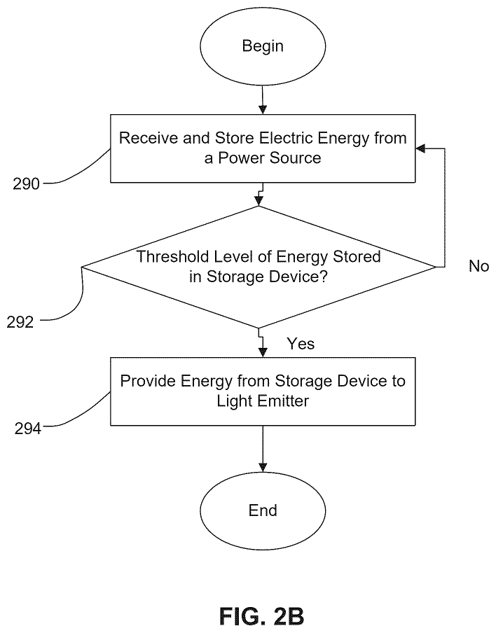

FIG. 2A is a schematic diagram of an illustrative light pulse generator consistent with the disclosed embodiments, while FIG. 2B is a flowchart highlighting illustrative methods for operation of the circuit of FIG. 2A. As shown at FIG. 2A, a circuit for driving a light emitter efficiently at low power may include a power source 205, a storage element 210, a pulse generator 217 working as part of or with a regulation module 215, and a light emitter 220, among other things.

The light emitter 220 comprises any suitable element that emits light when electric current at a particular voltage is applied to the light emitter. For example, the light emitter 220 may include a diode-based light emitter, e.g., a VCSEL, microLED, RCLED, etc.

The light emitter 220 may be characterized by a turn on voltage (V_{TO}), a threshold current (I_{TH}) and associated threshold voltage (V_{TH}), and a current range with associated voltages where the light emitter 220 transduces electrical energy to light with near maximum efficiency.

The power source 205 may include one or more devices configured to generate electric current and provide the electric current to one or more other components of the circuit 200 (e.g., the storage element 210) as electric energy. As used herein, the term “electric energy” (also referred to as “electric charge”) refers to potential energy as represented by a voltage associated with a stored charge and kinetic energy as represented by a combination of voltage and current in a circuit. For example, the power source 205 may comprise one or more photovoltaic (PV) cells configured to transduce incident light to electric energy. As used herein, the term “incident light” is intended to refer to any and all light energy impinging upon pertinent portions of the circuit 200, including, but not limited to the power source 205 implemented as one or more PVs. For example, the incident light may include ambient light (i.e., light surrounding the circuit), directed light (i.e., light from another device shined toward the circuit), etc.

A photovoltaic cell stack may be a series of semiconductor components connected in series, each of which is able to absorb light and transduce light energy to electricity in the form of a voltage and electric current. These semiconductor junctions may include light absorbing layers, semiconductor junctions, electrodes, or substrates, for example. One benefit of using a stack of a plurality of photovoltaic cells is to trade off voltage and current for a given function, since for a given light intensity and total area of photovoltaic, the product of output current and voltage is limited, but the particular amount of voltage is set by the number of photovoltaic cells in series. As described herein, at least two photovoltaic cell stacks may be used, one of which is configured to provide a higher voltage to the optical tag circuit, as compared to the other. This may be useful, for example, if some components require a higher voltage and others a lower voltage. As used herein, higher and lower are used for relative comparison, and do not indicate or imply any absolute range.

According to some embodiments, low voltage PVs may be implemented, the low voltage PVs comprising, for example, two silicon PIN junction photovoltaics in series configured to provide a total voltage of approximately 1.2 volts at an incident light intensity (i.e., illumination) of one milliwatt per square meter and approximately 0.8 volts at an illumination of one microwatt per square meter.

Alternatively, or in addition, the low voltage PVs may be implemented as one or more gallium arsenide (GaAs) PIN junction photovoltaic configured to provide approximately 1.1 volts at an illumination of one milliwatt per square millimeter, and approximately 0.8 volts at an illumination of one microwatt per square millimeter.

In one example, when implemented as one or more photovoltaic cells (PV), the power source 205 may include a plurality of PVs connected in series to provide an electric current proportional to the intensity of incident light on the PV. According to some embodiments the provided electrical current may approach a “short-circuit current” of the PV corresponding to a current when the voltage across the PV is approximately zero.

According to another example, depending on a desired voltage, the power source 205 may be implemented as a plurality of PVs connected in parallel. The parallel connected PVs may be configured to provide an electric current proportional to the intensity of incident light on the PV. The voltage output of the PVs may be related to the open-circuit voltage of the photovoltaics which is dependent on illumination conditions. Thus, according to an example, a plurality (e.g., 3) of GaAs PVs wired in parallel may be implemented to create a PV with an effective area of approximately 0.03 mm².

According to yet another example, and as will be discussed in greater detail below, a set of high voltage PVs may be provided alone or in conjunction with low voltage PVs, for example, to power a driver circuit and the regulation module 215, which may include a set of switches. An embodiment of the high voltage photovoltaics may include eight silicon PIN junction photovoltaics connected in series providing a total voltage of approximately 4.8 volts at an illumination of one milliwatt per square millimeter and approximately 3.2 volts at an illumination of one microwatt per square millimeter. Another embodiment of the high voltage photovoltaics could be five gallium arsenide PIN junction photovoltaic providing approximately 5.5 volts at an illumination of one milliwatt per square millimeter and approximately 4 volts at an illumination of one microwatt per square millimeter.

The storage element 210 may be configured to receive and store electric energy provided by any suitable power source, e.g., the power source 205 (step 290). For example, the storage element 210 may be implemented using one or more of a battery, a capacitor, a plurality of capacitors (also referred to as a bank of capacitors), etc. For example, as shown at FIG. 2A, a capacitor implemented as the storage element 210 is placed in parallel in the circuit 200 with the power source 205 and the light emitter 220.

When implemented as a capacitor, or a bank of capacitors, capacitance may range from about 200 pF to about 350 pF, and may be for example, 250 pF for an on-chip capacitor of a desired size (e.g., approximately 50,000 μm²). Notably, the configuration and values discussed with reference to FIG. 2A are illustrative and not intended as limiting.

According to some embodiments, the storage element 210 may be configured such that electric energy is provided from the power source 205 to the storage element 210 (e.g., a capacitor), to charge the storage element 210 with electric energy. For example, during periods where higher intensity incident light impinges upon one or more PVs of the power source 205, a larger amount of electric energy may be provided to the storage element 210 than during periods of low intensity or no light impingement. The electric energy provided to the storage element 210 may cause an increase in voltage across the storage element up to a point where voltage across the storage element approaches an open circuit voltage VOC of the power source 205 (essentially corresponding to a “full charge” condition). Current flow from the power source 205 to the storage element 210 may then reduce toward zero, and the voltage across the storage element may become approximately steady.

The regulation module 215 may be configured to regulate the flow of electric energy from the storage element 210 through the circuit to the light emitter 220. For example, the regulation module 215 may be configured to determine or otherwise measure a level of electric energy stored in the storage element 210 and compare the determined level of electric energy to a threshold electric energy corresponding to a predetermined current threshold of the light emitter (I_{TH}) at the threshold voltage V_{TH} of the light emitter 220 (step 296).

The regulation module 215 is configured such that until a pulse is required, (step 290) energy is accumulated, but when a pulse is needed (step 292) the accumulated energy is provided to the light emitter (step 292: yes). Then as this energy is used to power the light emitter, and so depleted from the storage element (step 294), the level of stored energy is monitored. As long as this level is determined to be greater than or equal to the threshold electric energy (step 296: yes), the electric energy stored in the storage element 210 continues to be available to the light emitter 220, and when the level is determined to be below the threshold electric energy (step 296: no), the pulse is terminated, and the electric energy stored in the storage element is restricted from reaching the light emitter 220, e.g., via opening of the switch element 219 and charging of the storage device continues.

According to some embodiments, the regulation module 215 may comprise one or more of a pulse generator 217 and a switch element 219 in communicative connection with the pulse generator 217, and configured to connect the storage element 210 and the power source 205 to the light emitter 220 to cause the light emitter to emit light in a pulse.

The pulse generator 217 may comprise an oscillator circuit configured to provide a relatively constant-period pulse train signal to function, for example, as an internal clock available in the circuit. According to one example, a relaxation oscillator may be used, with a reference current being charged to a small capacitor, for example, a capacitor ranging from 100 to 200 femto-Farads, e.g., 150 femto-Farads. A voltage of the small capacitor may be monitored and then discharged once it reaches a sufficient voltage (i.e., a voltage meeting criteria for light emission in the circuit in which it is operating). For example, a sufficient voltage may correspond approximately to an open circuit voltage of silicon (i.e., approximately 0.6V). This process may then repeat to create a periodic clock signal that has a relatively constant frequency, and the pulses may be used to drive components of the circuit 200, e.g., the switch element 219 at desired intervals.

The switch element 219 may comprise any suitable device for connecting and interrupting the flow of electric energy in a circuit. For example, the switch element 219 may comprise one or more metal-oxide-semiconductor field-effect transistors (MOSFET) in, for example, an integrated circuit implementation (e.g., a silicon semiconductor).

In such a configuration, the storage element 210 may quickly discharge to approximately VTO of the light emitter 220, at which point the current through the light emitter 220 may, as a result, be cut off or reduced to only that current available from the power source 205 until the switch element 219 is opened, thereby cutting off nearly all current to the light emitter 220. This in turn may allow the capacitor to recharge, for example in approximately 0.1 seconds or less. According to some embodiments, current pulses may be delivered by connecting the storage element 210 across the light emitter 220 via the switch element 219.

When a light pulse is desired from the light emitter 220, the regulation module 215 may cause current from the storage element 210 to be discharged through the light emitter 220 (step 294), e.g., via a pulse from pulse generator 217, which may in turn cause closing of the switch element 219. The pulse from the pulse generator 217 may be provided even when the level of electric energy is still below the open circuit voltage of the power source 205 V_{OC} (corresponding to a full charge condition), thereby quickly reducing voltage of the storage element 210 proportionally to the charge dissipated. The peak power of the pulse, corresponding to a point in the pulse of peak voltage Vₚₑₐₖ across the light emitter and so also corresponds to peak current Iₚₑₐₖ, through the emitter can be much greater than an average power available from the power source 205 and instead depends upon on the level of electric energy available in the storage element 210. The average power available from the source refers to the amount of power being continuously provided by the power source, and used to charge the storage element between pulses, whereas the power in the pulse can be higher as the pulse dissipates the energy available in the storage element over a shorter time. For example, according to embodiments associated with all of the circuits described herein, the peak power may be 1000 to 10000 times greater than the average available power from the power source 205, with a standby current consumed between each pulse being less than a range between 10⁻⁹ and 10⁻⁶, for example, about 10⁻⁸ Amps, where standby current corresponds to the current drawn by the optical tag circuit during periods in which no light is emitted by the light emitter.

In this context the power source 205 may act to continuously drive charge to the storage element 210, e.g., in the form of a smaller magnitude direct current. When a light pulse is to be emitted, the storage element 210 is electrically connected to and partially discharged through the light emitter 220 to generate a light pulse of a desired amplitude, for example, via the pulse generator driven switch element 219.

Under lighting conditions where sufficient DC electric energy is available, where “sufficient” refers to an amount of electric energy enabling recharge of the storage element 210 from approximately V_{TO} to V_{OC} between pulses (e.g., t<=0.1 seconds), the embodiment described above may continuously generate light pulses of a desired brightness, limited essentially by the available storage (e.g., capacitance) of the storage element 210, and the difference between V_{OC} and V_{TH}.

As available DC power, and particularly, short circuit current ISC diminishes, for example, under low light conditions when using photovoltaics, then the storage element 210 may not fully recharge to V_{OC}, and may not reach the high efficiency voltage range, meaning that pulses are disproportionately dim. Under sufficiently low light, the storage element 210 may not even recharge past the light emission threshold voltage V_{TH} of the light emitter 220, thereby dissipating electric energy but generating little or no light. Thus, control provided by the present embodiments results in light emission only when sufficient energy to generate a resolvable and readable light pulse from a light emitter, with charging occurring under low light conditions.

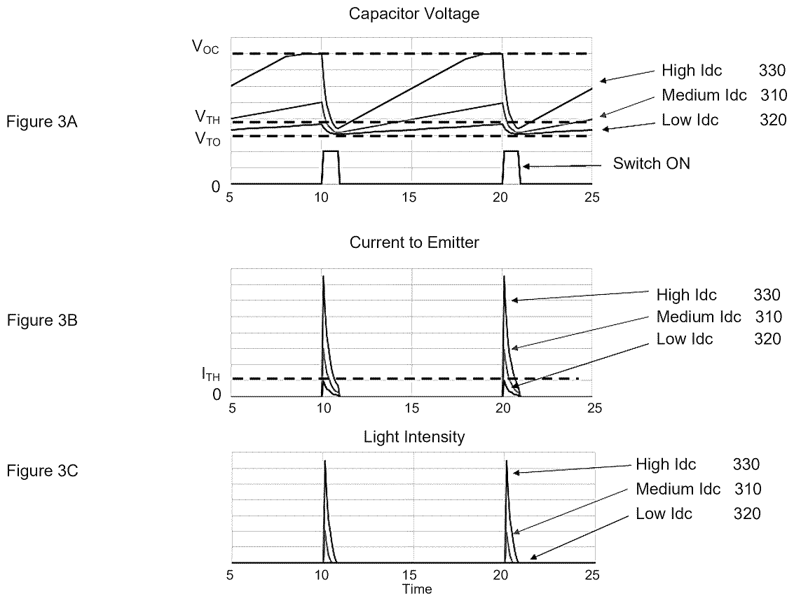

FIGS. 3A-C are graphs showing the impact of reducing available average current to a light-pulse generating circuit as illustrated in FIG. 2A. The plots show signals in the circuit 200 over two pulse cycles, for three different DC current levels (IDC) provided by the power source 205: low, medium and high, where medium current (trace 310) is three time the low current (trace 320) and high current (trace 330) is three times the medium current. FIG. 3A shows the voltage across the storage element 210, discharging during each pulse to close to V_{TO}, and recharging between pulses. FIG. 3B shows the current through the light emitter 220, and FIG. 3C shows the light emitted by the light emitter 220. Note that under low DC current, the storage element 210 does not recharge to V_{TH}, and so no light pulse was generated.

The circuit of FIG. 2A can be modelled by the following set of equations: Current through the VCSEL while turned on is set by:

$${I}_{VCSEL} ∼ \{ \begin{matrix}{g}_{ON} ( {V}_{VCSEL} - {V}_{TO} ) & {V}_{VCSEL} > {V}_{TO} \\ 0 & {V}_{VCSEL} \leq {V}_{TO}\end{matrix} \qquad ( 1 )$$

where g_{ON} is the differential inductance of the VCSEL Light from the VCSEL, then, will be:

$${L}_{out} ∼ \{ \begin{matrix}{η}_{max} ( {I}_{VCSEL} - {I}_{TH} ) & {I}_{VCSEL} > {I}_{TH} \\ 0 & {I}_{VCSEL} \leq {I}_{TH}\end{matrix} \} \qquad ( 2 )$$

Where is ηₘₐₓ is the maximum achievable quantum efficiency of the VCSEL Equation (2) may also be expressed in terms of voltage as shown at equation (3):

$${L}_{out} ∼ \{ \begin{matrix}{η}_{max} \cdot {g}_{ON} ( {V}_{VCSEL} - {V}_{TH} ) & {V}_{VCSEL} > {V}_{TH} \\ 0 & {V}_{VCSEL} \leq {V}_{TH}\end{matrix} \} \qquad ( 3 )$$

$$Where$$

$${V}_{TH} ∼ {V}_{TO} + {I}_{TH} / {g}_{ON} \qquad ( 4 )$$

If a pulse starts with a peak voltage of Vₚₑₐₖ corresponding to both the voltage across the accumulating capacitor and also to the peak power of the pulse, the pulse will discharge according to the equation:

V_{C}(t)~V_{TO}+(Vₚₑₐₖ−V_{TO})exp(−t g_{ON}/C) (5)

Where C is the capacitance of the energy accumulation capacitor. And current can be shown to be

I(t)~g_{ON}(V_{C}(t)−V_{TO})=g_{ON}(Vₚₑₐₖ−V_{TO})exp(−t g_{ON}/C) (6)

Thus, for Vₚₑₐₖ>V_{TH}, (and so, g_{ON} (Vₚₑₐₖ−V_{TO})>I_{TH}) light is emitted until

V_{TH}=V_{TO}+(Vₚₑₐₖ−V_{TO})exp(−t g_{ON}/C). (7)

The criteria of equation (7) will occur at time t_{TH} after the start of the pulse as shown at equation (8)

$${t}_{TH} = \frac{c}{{g}_{ON}} ln ( \frac{{g}_{ON} ( {V}_{peak} - {V}_{TO} )}{{I}_{TH}} ) \qquad ( 8 )$$

Total light emitted over the pulse, then goes as:

$${L}_{tot} = {\int }_{0}^{{t}_{TH}} {η}_{max} ( I ( t ) - {I}_{TH} ) dt = {η}_{max} C ( {V}_{peak} - {V}_{TO} ) ( 1 - exp ( - {t}_{TH} {g}_{ON} / C ) ) - {η}_{max} {I}_{TH} {t}_{TH}$$

which simplifies to:

$${L}_{tot} = {η}_{max} C ( {V}_{peak} - {V}_{TO} ) - {η}_{max} \frac{c}{{g}_{ON}} {I}_{TH} ( ln ( \frac{{g}_{ON} ( {V}_{peak} - {V}_{TO} )}{{I}_{TH}} ) + 1 ) \qquad ( 10 )$$

Assuming the storage element 210 is completely discharged (V_{C}→V_{TO}) during each pulse, and pulses are spaced by time T, then

$${V}_{peak} = min ( {V}_{OC} , {V}_{TO} + \frac{T \cdot {I}_{DC}}{C} ) \qquad ( 11 )$$

which, then allows estimation of total light emission for each pulse, based on pulse spacing, capacitance, and emitter properties (V_{TO}, g_{ON} and I_{TH}):

$${L}_{tot} = {η}_{max} \{ \begin{matrix}C ( {V}_{OC} - {V}_{TH} ) - C \frac{{I}_{TH}}{{g}_{ON}} ( ln ( \frac{{g}_{ON} ( {V}_{OC} - {V}_{TO} )}{{I}_{TH}} ) + 1 ) & when & ( {V}_{OC} - {V}_{TO} ) < \frac{T \cdot {I}_{DC}}{C} \\ T \cdot {I}_{DC} - C \frac{{I}_{TH}}{{g}_{ON}} ( ln ( \frac{{g}_{ON} \cdot T \cdot {I}_{DC}}{C \cdot {I}_{TH}} ) + 1 ) & when & ( {V}_{OC} - {V}_{TO} ) > \frac{T \cdot {I}_{DC}}{C} > \frac{{I}_{TH}}{{g}_{ON}} \\ 0 & when & \frac{T \cdot {I}_{DC}}{C} < \frac{{I}_{TH}}{{g}_{ON}}\end{matrix} \qquad ( 12 )$$

Thus, as noted above, when sufficient DC current is available, pulse brightness may be determined as a function of storage element capacity (e.g., capacitor size), open circuit voltage V_{OC} of the power source 205, and the VCSEL properties g_{ON}, V_{TO}, I_{TH}, and V_{TH}. However, as available current decreases, pulse amplitude decreases nonlinearly, falling to zero before available current has reached zero.

### Example 1

| Variable | Value for the Example | Units |
|---|---|---|
| V_{TO} | 1.5 | V |
| I_{TH} | 1 | mA |
| V_{TH} | 1.8 | V |
| g_{ON} | 3 | mS (milliSiemens) |
| T | 10 | Ms (milliseconds) |
| C | 250 | pC |
| V_{OC} | 4 | V |
| I_{DC} (Isc) | 2.5-250 | nA |

In the following example a set of representative quantitative values to the parameters in the equations above, are provided. These following should not be considered as limiting and is provided for illustration and aid in understanding of the described embodiments.

A typical light emitter 220 implemented by a VCSEL may have a turn on voltage V_{TO} of approximately 1.5V, with an on conductance of approximately 3 milliSiemens (such that I=(V−1.5V)*0.003). A typical threshold current is approximately 1 mA, implying a threshold voltage of ~1.8V. This also means that the light emitter 220 can achieve about half of its maximum efficiency only for voltages greater than 2.1V.

For a circuit 200 running based on ambient light levels from approximately 1 mSun (indoor lighting) to 100 mSun (outdoors), and with a power source 205 implemented as one or more PVs, electric current per PV cell may be approximately 250 pA/μm²/sun, for an open-circuit voltage of approximately 0.8V. Thus, a photovoltaic cell stack of five 100 μm×100 μm PVs may provide V_{OC}=4V, Isc=2.5 nA (at 1 mSun) to 250 nA (at 100 mSun).

In this example, an on-chip capacitor having a capacitance of approximately 250 pF is implemented as the storage element 210.

Then assuming a minimum pulse spacing of approximately 10 milliseconds, between pulses, the PVs can charge the storage element 210 (e.g., the capacitor) by between 100 mV (at 1 mSun) up to the V_{OC}.

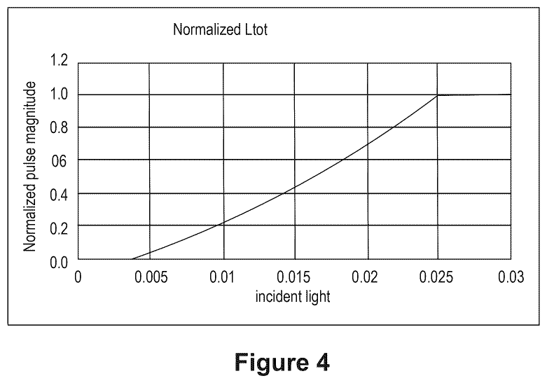

According to the present example, no light will be emitted from the light emitter 220 until incident light is greater than 3 mSun. FIG. 4 is a graph of normalized output light/pulse vs incident light according to the present example, and shows that turn on of the light emitter 220 is nonlinear, such that approximately 5 mSun is necessary before a light level from the light emitter 220 begins to rise.

Thus, under conditions of low available DC power (e.g., low light conditions), when trying to drive the light emitter 220 in an efficient manner, switching alone can lead to undesirably small (e.g., unresolvable), or even nonexistent output light pulses. Therefore, it may be desirable to use brief pulses of current to drive the light emitter 220 in combination with techniques to ensure that the current/voltage across the light emitter 220 and the storage element 210, i.e., a level of available electric energy, remain above a lower threshold limit during pulse intervals. Specifically, when a voltage of the storage element 210, and the associated current through the light emitter 220 fall below a predetermined current threshold, the current to the light emitter 220 can be cut off, i.e., restricted or prevented from reaching the light emitter 220, thereby stopping discharge of the storage element 210.

By setting this minimum threshold voltage level (interchangeably referred to as a “floor”) to be greater than or equal to the light-emission threshold voltage (V_{TH}) (and so current (I_{TH})) of the light emitter 220, efficiency can be improved because little to no energy will be wasted in discharging current through the light emitter 220 at levels that do not generate resolvable/discernable light.

Notably, greater efficiency may be achieved by setting the current and/or voltage floor to a bottom end of a high-efficiency range of currents and/or voltages, to ensure that electric energy is sent to the light emitter 220 in a mode that most efficiently generates light. The floor can be achieved according to the following described embodiments.

### Fixed and Light-Level Adaptive Pulse Width Control

A pulse length TPW may be set to a fixed, preprogrammed period short enough to avoid discharging the storage element 210 below a desired floor. In such an embodiment, a precision timing circuit (not shown) may be provided to control the pulse generator 217 to generate short switch control pulses, for example, in the nanosecond range with similar (ns) levels of precision. From the equations above, t_{TH} can be determined to be a fixed number, and thus, it may not be assumed that the storage element will discharge to V_{TO}, but instead to a minimum voltage:

Vₘᵢₙ~V_{TO}+(Vₚₑₐₖ−V_{TO})exp(−t_{TH}JON/C)

and thus:

$${V}_{peak} = min ( {V}_{OC} , {V}_{min} + \frac{T \cdot {I}_{DC}}{C} ) \qquad ( 13 )$$

Which, together implies:

$${V}_{peak} = min ( {V}_{OC} , {V}_{TO} + \frac{T \cdot {I}_{DC}}{C ( 1 - exp ( - {t}_{TH} {g}_{ON} / C )} ) \qquad ( 14 )$$

Then applying these parameters to equations 8 and 9 above, we can derive the total light per pulse, Lₜₒₜ, to be:

$${L}_{tot} = {η}_{max} \{ \begin{matrix}C ( {V}_{OC} - {V}_{TO} ) ( 1 - exp ( - {t}_{TH} - {g}_{ON} / C ) ) - {I}_{TH} {t}_{TH} , & when & C ( {V}_{OC} - {V}_{TO} ) ( 1 - exp ( - {t}_{TH} - {g}_{ON} / C ) ) < T \cdot {I}_{DC} \\ T \cdot {I}_{DC} - {I}_{TH} {t}_{TH} & when & C ( {V}_{OC} - {V}_{TO} ) ( 1 - exp ( - {t}_{TH} - {g}_{ON} / C ) ) > T \cdot {I}_{DC} > {I}_{TH} {t}_{TH} \\ 0 & when & T \cdot {I}_{DC} < {I}_{TH} {t}_{TH}\end{matrix} \qquad ( 15 )$$

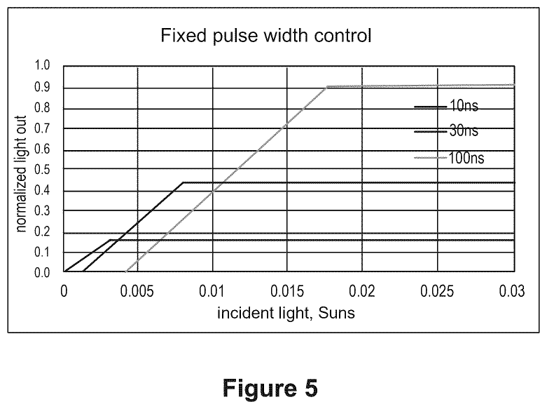

Plotting light per pulse as a function of incident light for the example parameters given above, for different fixed pulse widths, T_{PM}, gives the results shown in FIG. 5, which shows total light out (integrated over the full fixed pulse, and normalized to a maximum possible value) as a function of fixed pulse width (T_{PM}=10 ns, 30 ns, or 100 ns) and incident light level. Review of the plots show that at low light levels, a shorter pulse may be desirable, while at higher incident light levels, a longer pulse may be desirable.

Using such a fixed pulse provides good efficiency for a specific amount of available power, however, such a technique may be less efficient if available power is more or less than the desired range. To address this an adjustable pulse-generator circuit that sets the pulse to a period corresponding to an amount of continuous power available from the power source 205, for example, based on incident light, can be used to improve the pulse width/duration. This approach may implement a precision, tunable timing circuit, enabling changing of pulse length based on incident light. For example, the pulse length may be increased when more power is available, while the pulse length may be decreased to maintain efficiency when little power is available from the power source 205.

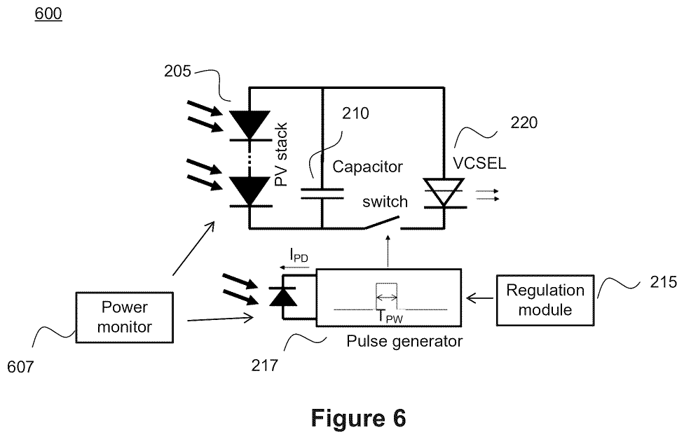

Building on the circuit 200 of FIG. 2, FIG. 6 shows an illustrative schematic diagram of a light-level adaptive pulse-width (T_{PM} proportional to I_{PD}) controlled light pulse generator, where IPD is the current from a photodetector, which may be proportional to the current available from the photovoltaics. Importantly, the circuit 600 of FIG. 6 shares various components with the circuit 200 of FIG. 2, and the shared components function in a similar manner between the two circuits.

According to embodiments, a power monitor 607 configured to monitor a level of available energy from the power source 205 and/or the storage element 210 is provided with the circuit 600. For example, the power monitor 607 may include one or more of a light level sensor, a voltage sensor, a current sensor, etc. enabling a measurement of electric power available from the power source 205 and/or the storage element 210. According to such an example, where the power source 205 comprises one or more PV cells configured to transduce incident light into electric energy, the power monitor 607 may comprise a light sensor configured to measure, for example, light absorbed by the one or more PVs of the power source 205, an amount of current flowing to storage element 210, a voltage of storage element 210, etc.

The pulse generator 217 may receive a signal indicative of available energy from the power monitor 607, and proportionally adjust the pulse duration of the pulse based on the available energy (e.g., based on the intensity of incident light on the circuit). For example, the pulse duration may be determined such that pulse energy for the pulse duration remains below the available energy throughout the pulse duration, and wherein the pulse energy is configured to cause the light emitter 220 to produce light at a predetermined intensity for each pulse.

According to such an example, a desired intensity of an encoded optical signal generated by the light emitter 220 may correlate to the average power corresponding to the electric energy available from the power source 205 and/or the storage element 210. For example,

### Example 2

| Variable | Value | Units |
|---|---|---|
| T_{PM} | 10-100 | ns |
| V_{TO} | 1.5 | V |
| I_{TH} | 1 | mA |
| V_{TH} | 1.8 | V |
| g_{ON} | 3 | mS (milliSiemens) |
| T | 10 | ms (milliseconds) |
| C | 250 | pC |
| V_{OC} | 4 | V |
| I_{DC} (Isc) | 2.5-250 | nA |

### Current Source Control of Current Through the Light Emitter

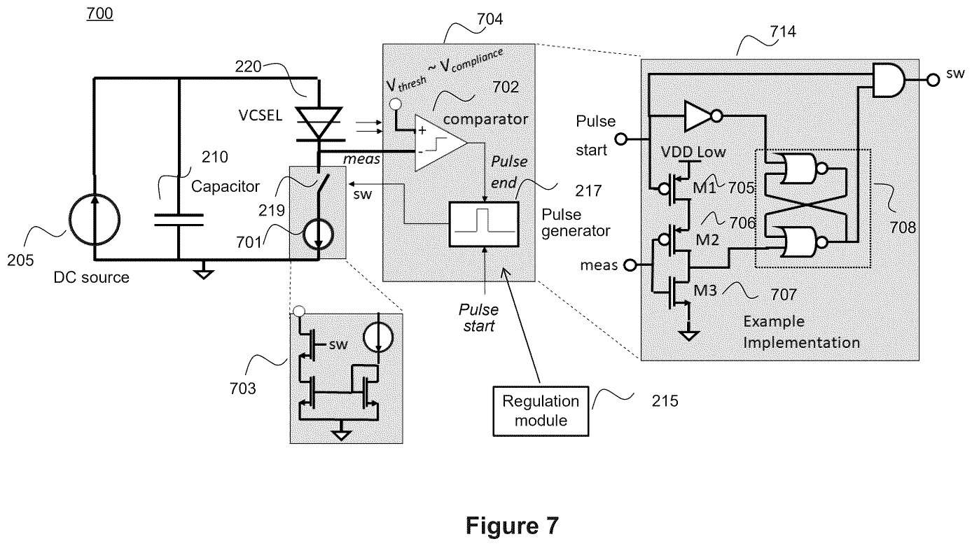

FIG. 7 shows an example of a current-driven light emitter 220 circuit having a current source 701 implemented, for example, in series, with the light emitter 220. The power source 205 and/or the storage element 210 may be configured to operate as, for example, the current source 701. Such a current source 701 may be configured to operate with one or more switches 219 to quickly allow or prevent current from reaching the light emitter 220.

In addition to the current source, a comparison circuit may be implemented and configured to compare a voltage on the anode of the light emitter 220 to a compliance voltage of the current source 701, and/or an operational voltage threshold. The compliance voltage may correspond to a voltage above which the current from the current source 701 is maintained as constant, and below which the current source acts more like a resistor such that current rapidly falls to approximately zero as the volta across the current source falls to zero. By using the comparator to turn off the current source before the output voltage falls below the compliance voltage, this may allow the circuit to reduce wasted power attempting to drive the light emitter 220 with sub-optimal current levels, while allowing the light emitter 220 to continue emitting light as long as possible if the voltage (and so current) levels are available to drive the light emitter 220 effectively. According to embodiments, an “effectively” driven light emitter 220 corresponds to emission of light at which a desired reader device is enabled to detect and resolve the emitted light under ambient conditions.

According to some embodiments, the current source 701 may be connected in series with the light emitter 220 to provide a regulated current at a level greater than the emitter threshold current I_{TH} that the light emitter 220. The current from the current source 701 may be set to a level that provides efficient emission of light from the light emitter 220, for example in the maximum efficiency range.

As noted above, the power source 205 may be implemented as one or more photovoltaic elements receiving incident light. In such an embodiment, when the brightness of incident light decreases, such that less energy is accumulated between pulse, it may be more efficient when the steady current from the current source is adaptively increased, to more efficiently generate light, but over a shorter pulse duration.

The current source may be implemented using a current mirror that provides a fixed current to the light emitter 220.

According to an example, when implementing a MOSFET-based current mirror, the compliance voltage may be, for example, Vdsat, corresponding to the minimum voltage for keeping the MOSFET transistors in saturation.

During periods when the pulse generator 217 is not generating a pulse, the current source may be turned off. When a pulse occurs, for example, when sending one or more bit(s) of data, a comparison circuit 704 may be implemented to detect when the voltage across the current source 701 approaches or falls below the compliance voltage, such that the flow of current can then be terminated.

According to some embodiments, the comparison circuit 704 is configured with a comparator 702 to compare the voltage across the current source 701 to the predetermined compliance voltage. The comparator 702 may be any suitable device for performing the voltage comparison, for example, complementary metal-oxide semiconductor (CMOS) inverter having a plurality of transistors M1 705, M2 706, M3 707 connected in series. According to such an example, the compliance voltage of the current source 701 may be determined based on the number of transistors implemented in the comparator 702. While the present example shown at FIG. 7 includes an implementation in which three transistors M1 705, M2 706, and M3 707 have been implemented, this is not intended as limiting, and any suitable number of transistors may be implemented within the comparator 702 depending on, for example, a desired compliance voltage, among other things. According to some embodiments, between 2 and 6 transistors may be implemented.

The comparator 702 may further include a set-reset (SR) latch 708 configured, for example, to include a pair of cross coupled NOR logic gates.

Thus, the circuit 700 can be configured as a current-driven light pulse driver implementing a comparator 702 to set a voltage floor, i.e., a lower threshold voltage Vₜₕᵣₑₛₕ corresponding to a desired voltage at which the light emitter 220 may be operated. According to some embodiments, the threshold voltage may be set to achieve, for example, an elevated or even maximized efficiency of light emission from the light emitter 220, with the pulse generator 217 used to control the timing of pulses of electric energy to the light emitter 220.

For example, a pulse may be generated by the pulse generator 217 following the rising edge of an input signal, e.g. “Pulse Start,” and terminate when the voltage on node “meas” falls below the threshold voltage (Vₜₕᵣₑₛₕ). In such an example, Vₜₕᵣₑₛₕ may approximate the compliance voltage, V_{compliance}.

Current source inset 703 shows illustrative components that may be implemented to form the current source 701, consistent with some embodiments. Similarly, comparator inset 714 shows illustrative components that may be implemented to form the comparison circuit 704, according to some embodiments. The components shown at FIG. 7 are not intended as limiting, and other configurations are contemplated by the inventors.

In this example implementation of the comparator 704, the threshold may be set by the relative sizing and/or properties of the three transistors M1 705, M2 706, and M3 707. The digital output and “pulse start” drive the SR latch 708, whose output is combined as an AND with the “pulse start” to generate the “sw” output. When “pulse start” is low, the SR latch 708 is set high, but “pulse start” remains set low, so the output “sw” is off. When “pulse start” is high, the SR latch 708 may enter a hold state, so output of the SR latch 708 stays high, but at this point “sw” is also high. Once the voltage on “meas” falls below a threshold corresponding to approximately the compliance voltage of the current source, the SR latch 708 is reset to be low, driving “sw” low and thus ending the pulse until “pulse start” is cycled low and then high again at the start of the next pulse.

According to some embodiments, the current source may be connected in series with the switch element 219 operated, at least in part, by the SR latch 708. According to some embodiments, the SR latch 708 is further connected to a comparator and logic gates that may operate together to initiate the pulse by a rising edge of a control input voltage and terminate the pulse when the voltage across the current source is below the compliance threshold. A control input voltage, for example, may be a signal provided as an input from an optical signal encoder determining when to send pulses.

As a non-limiting example, with an on current of I_{ON}>>I_{TH}, or the threshold current, the compliance voltage V_{comp}, may generate pulses of length according to equation (16):

$${t}_{pulse} = \frac{c}{{I}_{on}} ( {V}_{peak} - {V}_{comp} - {V}_{TO} - \frac{{I}_{on}}{{g}_{on}} ) \qquad ( 16 )$$

the peak capacitor voltage may be determined by equation (17):

$${V}_{peak} = min ( {V}_{OC} , {V}_{comp} + {V}_{TO} + \frac{{I}_{on}}{{g}_{on}} + \frac{T \cdot {I}_{DC}}{C} ) . \qquad ( 17 )$$

And similar to equations 8-12 above, total light pulse intensity may be determined as

$${L}_{tot} = {η}_{max} \cdot {t}_{pulse} \cdot ( {I}_{on} - {I}_{TH} ) = {η}_{max} \frac{{I}_{on} - {I}_{TH}}{{I}_{on}} min ( T \cdot {I}_{DC} , C ( {V}_{OC} - {V}_{comp} - {V}_{TO} - \frac{{I}_{on}}{{g}_{on}} ) ) \qquad ( 18 )$$

on current I_{ON} may be limited such that its maximum value does not exceed:

Iₒₙ<gₒₙ(V_{OC}−V_{comp}−V_{TO}) (19)

For high input current I_{DC}, where the storage element 210 (e.g., a capacitor) can be expected to recharge to Voc, then a desired configuration for Iₒₙ may be the geometric mean of this maximum current and I_{TH} as determined at equation (20):

I_{on_opt}=\sqrt{(V_{OC}−V_{comp}−V_{TO})I_{TH}gₒₙ} (20)

### Example 3

| Variable | Value | Units |
|---|---|---|
| V_{compliance} | 0.4 | V |
| Iₒₙₒₚₜ | 2.5 | mA |
| V_{TO} | 1.5 | V |
| I_{TH} | 1 | mA |
| V_{TH} | 1.8 | V |
| g_{ON} | 3 | mS (milliSiemens) |
| T | 10 | Ms (milliseconds) |
| C | 250 | pC |
| V_{OC} | 4 | V |
| I_{DC} (Isc) | 2.5-250 | nA |

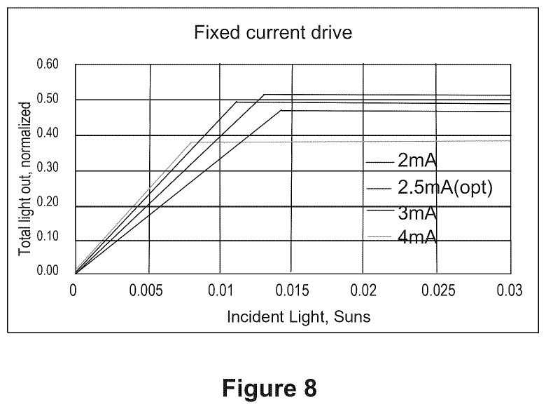

This can be seen in FIG. 8, which is a graphical representation of a light pulse generator operating with a fixed current. When T·I_{DC}«C(V_{OC}−V_{comp}−V_{TO}), improved efficiency is possible by increasing Iₒₙ>I_{on_opt}. Comparing to FIGS. 4 and 5, it can be seen that even at approximately optimal current, maximum light out may be less than what is possible with simple switches. However, in contrast, and according to the present example, a light pulse may always be generated provided the on current exceeds the threshold current (Iₒₙ>I_{TH}).

At FIG. 8, total emitted light is plotted vs incident light as measured in suns. With a compliance voltage V_{comp}=0.4V, as an example, and normalized to the same peak value, as incident light increases, while setting a constant current using the current source, as shown in FIG. 7, the emitted light appears to increase linearly until it reaches a threshold output.

According to such an example, a circuit can be implemented at low power since the compliance voltage can set the required voltage supply of the comparator relatively low. Such an approach in a semiconductor circuit at low power can require a relatively high-ratio current mirror, which can be slow to effectively turn on and off at low power, and which tends to be larger and less efficient than driving the light emitter 220 with a low-resistance switch element 219.

### Low Power Source Using a Voltage-Based Floor

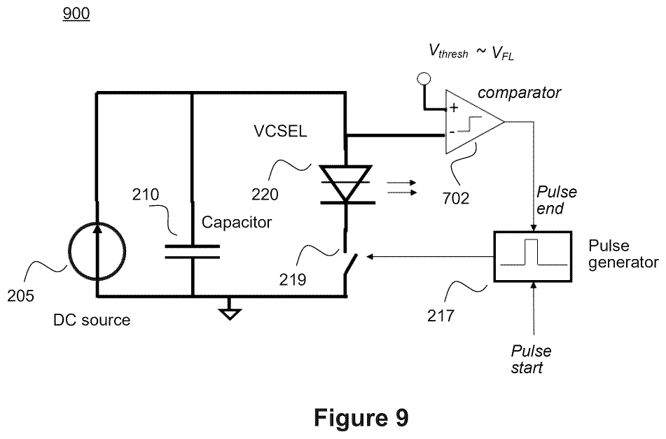

FIG. 9 is a schematic diagram of another illustrative optical tag circuit. According to embodiments of FIG. 9, a voltage floor circuit may be implemented building on the previously described circuits and including similar elements found therein. According to the present, non-limiting example, a capacitor is implemented as the storage element 210, a VCSEL for the light emitter 220, and the power source 205, represented as a DC source, may be implemented as one or more PVs, as described above.

According to circuit 900 of FIG. 9, a voltage floor threshold VFL is introduced in the control loop for the pulse generator 217, such that the switch element 219, which controls the flow of electric energy to the light emitter 220, closes to allow such flow when the voltage across the power source 205 and/or storage element 210 is greater than the voltage floor threshold, V_{F¬L}. In this example, the comparator threshold, Vₜₕᵣₑₛₕ, is approximately equal to the voltage floor threshold V_{FL}.

According to some embodiments, the voltage floor threshold V_{FL} may be set equivalent to the threshold voltage V_{TH} above which the light emitter will emit light. As previously noted, the light emitter 220 may include a VCSEL, which can be operated in an efficient state, based on a desired current and voltage, throughout the entire pulse. Therefore, according to alternative embodiments, the voltage floor threshold may be set to a voltage at which the light emitter 220 emits light at a desired efficiency.

To accomplish the above, the pulse generator 217 may be switched from an “off” state to an “on” state in accordance with the information (e.g., a unique identifier of a tag in which the circuit operates, unique identifier of an object, etc.) to be transmitted and switched “off” by the comparator 702 when the voltage is lower than the voltage floor threshold V_{FL}. Thus, the comparator 702 may be configured to compare the voltage across the storage element 210 and/or power source 205 to the voltage floor threshold V_{FL}, and provide a corresponding output to the pulse generator 217 to cause control of the pulse.

Notably, when the voltage floor threshold level is set greater than the light emitter threshold voltage V_{TH}, the light emitter may emit light more efficiently. Therefore, the comparator 702 may be configured with a voltage floor threshold V_{FL} at which the light emitter 220 emits light at a desired efficiency, thereby controlling pulse generator 217 to trigger pulses for opening and closing the switch element 219, for example, to achieve the desired efficiency.

According to some embodiments, the voltage floor level may be configurable, for example, from within the circuit itself and/or based on data input (e.g., from a configuration memory of the circuit), which may allow an optimization based on properties including but not limited to the type of light emitter 220, or available power from the power source 205 or storage element 210, for example.

The voltage across the storage element 210 (e.g., a capacitor) may be relatively large, for example in the range of 2-5V. However, in a low power system, most of the circuitry may operate at a lower voltage, for example <1V. In such an example, the circuitry may be incompatible with a comparison circuit comparing voltages greater than 2V to a threshold. Thus, according to some embodiments, a voltage offset, or voltage bias element, may be placed in between a comparison circuit input and the power source 205 or storage element 210.

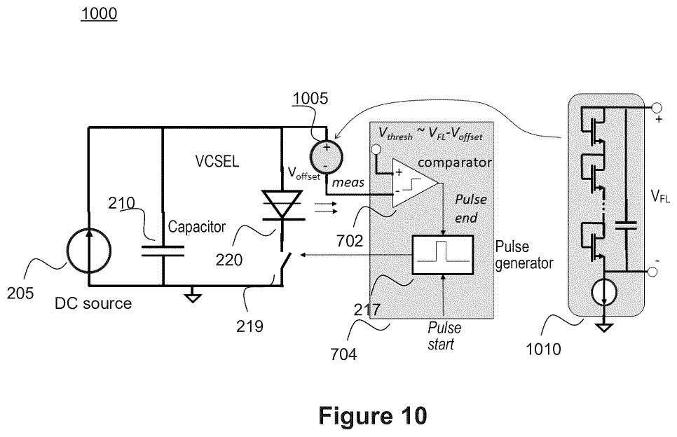

FIG. 10 is a schematic diagram of another illustrative optical tag circuit including a voltage bias element 1005. The circuit 1000 of FIG. 10 builds on the circuits previously disclosed herein and includes a number of elements in common with such circuits. Alternatively, many of the elements of the circuit 1000 can be, for example, digital, including the comparator 702, with the voltage bias element 1005 being analog.

In this example, a voltage bias element 1005, configured to introduce a voltage bias V_{offset}, is located between the power source 205 and/or storage element 210 and provides the voltage bias as an input to the comparator 702. The comparison circuit input may be, for example, the inverting or non-inverting input node of an operational amplifier or comparator. The bias voltage input to the comparison circuit enables a comparison of the voltage offset input to a desired light emitter voltage threshold for controlling when light may be emitted from the light emitter 220. For example, the light emitter 220 voltage threshold may be equivalent to the threshold above which the light emitter 220 emits light, and therefore, electric energy may not be provided to the light emitter 220 at levels where no light would be produced, otherwise wasting electric energy.

According to some other embodiments, the bias voltage may be set equivalent to a level above which the light emitter 220 emits light monotonically, or in proportion to the current flowing through the light emitter 220, thereby ensuring greater efficiency and limiting waste of electric energy.

The bias voltage may be adjustable based on, for example, an average power from the power source 205 available over time.

According to some embodiments, the comparison circuit uses a comparator 702, including, for example, a CMOS inverter operating with one or more transistors in series. In such an embodiment, the quantity or size of the transistors may determine the bias voltage provided by the voltage offset.

Similar to some of the examples shown in previous figures, the comparison circuit 704 may respond to a pulse provided by the pulse generator 217 and when the voltage offset falls below the voltage threshold, the comparison circuit 704 may cause the pulse generator 217 to terminate the pulse, resulting in opening of the switch element 219 and restricting current from reaching the light emitter 220.

The other input of the comparator corresponds with the comparator voltage threshold, V_{thresh¬}, which may be set approximately equal to the difference between a voltage floor, V_{FL}, above which the light emitter 220 emits light efficiently, and V_{offset}. Consistent with some embodiments, the voltage bias element 1005 may comprise a plurality of transistors (e.g., three transistors) and at least one capacitor in series with the plurality of transistors, as shown in the enlarged voltage bias element 1010.

The effect of such a circuit may include, for example, that the comparator operates at a lower voltage, offset from the power source 205 and/or storage element 210, thereby preventing the light emitter 220 from emitting light in an inefficient region of the light emitter 220.

By preventing the voltage of the storage element 210 from falling below the comparator voltage threshold, the circuit can ensure that at least some perceptible light is emitted for every pulse. Furthermore, by setting the voltage threshold of the comparator somewhat above the light emitter 220 threshold voltage, the light emitter 220 can be driven in a region of reasonable quantum efficiency for every pulse. The term “quantum efficiency” as used herein, is intended to refer to the level of efficiency of converting electric energy to light by a circuit element, or vice versa.

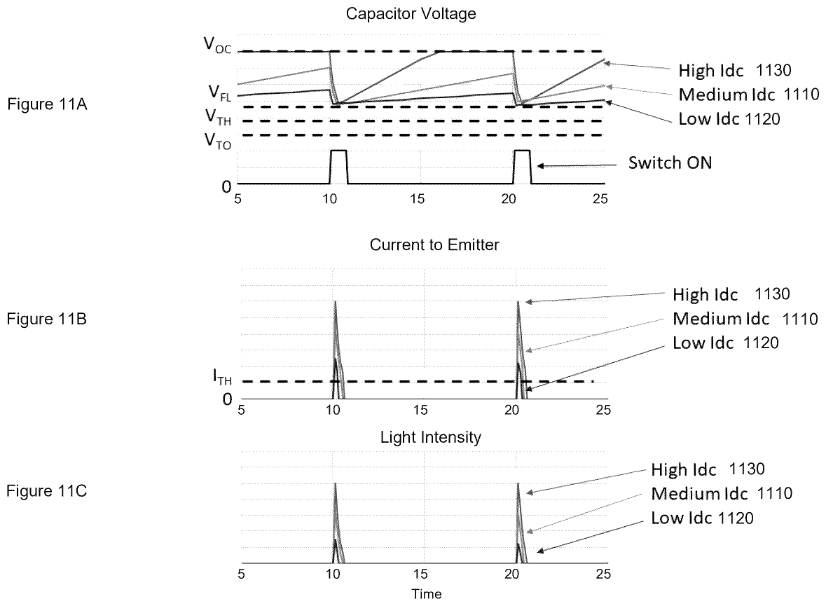

Examples of storage element 210 voltage, light emitter 220 current, and output light intensity are shown in FIGS. 11A-C. Shown in each figure are traces corresponding to low 1120 (red), medium 1110 (green), and high 1130 (blue) circuit current, I_{DC}, in response to two pulse cycles, not necessarily shown with any accuracy in regard to timing. In this example, the storage element 210 is a capacitor. As shown in FIG. 11A, at high current, the open circuit voltage, V_{OC}, is reached easily while charging the capacitor between pulses. Below V_{OC}, but above the voltage floor, V_{FL}, capacitor voltage rises monotonically, consistent with some embodiments. During each pulse, the capacitor discharges its electric energy to the light emitter 220. In this example, the light emitter 220 is a VCSEL. FIG. 11B shows the current through the VCSEL over time. Even in a low IDC situation, the pulses provide enough current to drive the VCSEL, as during every pulse the current goes above the light emitter 220 threshold current, I_{TH}. This is further exemplified by the fact that the capacitor voltage now always stays above the light emitter threshold voltage, V_{TH}, and therefore well above the turn-on voltage, V_{TO}, as compared to the circuit shown in FIG. 2A for example, so light is generated for every pulse.

Compared to the previously described circuits above, in the circuit 1000,

$${V}_{peak} = min ( {V}_{OC} , {V}_{FL} + \frac{T \cdot {I}_{DC}}{C} ) \qquad ( 21 )$$

and the switch element 219 turns off when the voltage reaches the floor voltage V_{FL} (chosen such that V_{FL}>V_{TH}) at time t_{FL}. Similar to the derivation of Eq. 8:

$${t}_{FL} = \frac{c}{{g}_{ON}} ln ( \frac{{V}_{peak} - {V}_{TO}}{{V}_{FL} - {V V}_{TO}} ) \qquad ( 22 )$$

Applying equation 9, and following a similar derivation as above, the total emitted light per pulse is:

$${L}_{tot} = {η}_{max} C [ ( {V}_{peak} - {V}_{FL} ) - \frac{{I}_{TH}}{{g}_{ON}} ln ( \frac{{V}_{peak} - {V}_{TO}}{{V}_{FL} - {V}_{TO}} ) ] \qquad ( 23 )$$

which, based on eq. 21 gives a value:

$${L}_{tot} = {η}_{max} C \cdot min ( \begin{matrix}( {V}_{OC} - {V}_{FL} ) - ( {V}_{TH} - {V}_{TO} ) ln ( \frac{{V}_{OC} - {V}_{TO}}{{V}_{FL} - {V}_{TO}} ) , \\ \frac{T \cdot {I}_{DC}}{C} - ( {V}_{TH} - {V}_{TO} ) ln ( 1 + \frac{T \cdot {I}_{DC}}{C ( {V}_{FL} - {V}_{TO} )} )\end{matrix} ] \qquad ( 24 )$$

### Example 4

| Variable | Value | Units |
|---|---|---|
| V_{FL} = Vₜₕᵣₑₛₕ + V_{offset} | 1.8-3.0 | V |
| V_{TO} | 1.5 | V |
| I_{TH} | 1 | mA |
| V_{TH} | 1.8 | V |
| g_{ON} | 3 | mS (milliSiemens) |
| T | 10 | Ms (milliseconds) |
| C | 250 | pC |
| V_{OC} | 4 | V |
| I_{DC} (Isc) | 2.5-250 | nA |

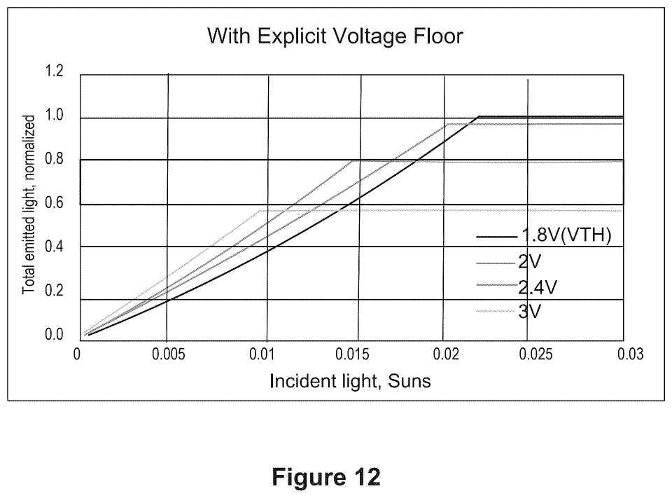

Plots of the output emitted light, Lₜₒₜ from eq. 24 as a function of incident light for several different floor voltages, _{VFL}, are shown in FIG. 12. The same parameters and normalization are used here, as from FIGS. 4, 5, and 8. For V_{FL}>V_{TH¬}, where V_{¬TH¬} is the voltage threshold of the comparator, pulses will always generate light. As incident light increases, the same maximum is reached as shown in FIG. 4, but here the maximum is achieved at a lower incident light level. For example, a VCSEL may be driven to lase at incident light levels of less than 0.003 Suns, while the circuit 1000 uses an average power from the power source 205 of less than 10 nanowatts. Increasing V_{FL} may increase the pulse amplitude at lower incident light levels, with some cost to maximum amplitude at high incident light levels. Such a circuit may be optimized such that V_{FL} is adjustable based on the available average power from the power source 205 or storage element 210, in accordance with some embodiments.

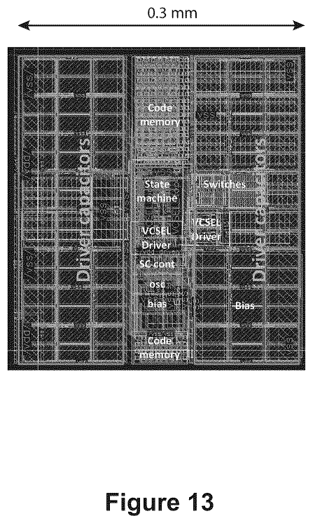

An illustrative physical integrated circuit layout of such a circuit is shown in FIG. 13, implemented in 180 nanometer CMOS. This example uses a VCSEL as the light emitter 220, a bias voltage element 1005, switches 219, and capacitors as the storage element 210. In this example, the entire design occupies an area less than 0.3 mm by 0.3 mm, while being capable of driving a VCSEL to lase using an average of approximately 3 nanowatts of power from the power source 205 or storage element 210.

While the examples described herein have been directed to free-space (wireless) optical communications, the techniques described can also be used in contexts where the encoded optical signal is coupled into an optical wave guide or optical fiber.

Further, it should be noted that similar problems arise when using light sources for sensing in power constrained contexts, such as in spectroscopy, where a controlled light source (typically a laser, such as a VCSEL) is used to detect and identify different chemical species. Thus, the embodiments described herein can be implemented not only in power-constrained optical communications, but also in a variety of optical sensing modalities.

The foregoing description has been presented for purposes of illustration. It is not exhaustive and is not limited to the precise forms or embodiments disclosed. Modifications and adaptations will be apparent to those skilled in the art from consideration of the specification and practice of the disclosed embodiments.

The foregoing description has been presented for purposes of illustration. It is not exhaustive and is not limited to the precise forms or embodiments disclosed. Modifications and adaptations of the embodiments will be apparent from consideration of the specification and practice of the disclosed embodiments. For example, the described implementations include hardware and software, but systems and methods consistent with the present disclosure may be implemented as hardware alone. Various embodiments are described by the following set of clauses:
Clause 1. An optically powered electronic circuit to drive a light emitter at low power, the circuit comprising: a storage element configured to store electric energy; a power source configured to generate electric current and provide the electric current to the storage element for storage as electric energy; and a regulation module configured to determine a level of electric energy stored in the storage element and compare the level of electric energy to a threshold electric energy corresponding to a predetermined current threshold of the light emitter, wherein: the regulation module is configured such that: when the level is determined to be greater than or equal to the threshold electric energy and information is to be transmitted by the circuit, the electric energy stored in the storage element is provided to the light emitter in a pulse, and when the level is determined to be below the threshold electric energy, the electric energy stored in the storage element is restricted from reaching the light emitter, and wherein a peak power of the pulse is greater than an average power available from the power source.
Clause 2. The circuit of clause 1, wherein the storage element comprises at least one capacitor configured to provide electric energy.
Clause 3. The circuit of any of clauses 1-2, wherein the power source is further configured to transduce incident light to generate the electric current.
Clause 4. The circuit of clause 3, wherein the power source is comprised of photovoltaic cell stack connected in series and configured to provide electric current in proportion to the amount of incident light collected by the photovoltaic cell stack.
Clause 5. The circuit of clause 4, wherein the power source further comprises a photovoltaic cell stack connected in parallel and configured to provide electric energy in proportion to the amount of incident light collected by the photovoltaic cell stack.
Clause 6. The circuit of any of clauses 1-5, further comprising: a pulse generator configured to generate the pulse, wherein the regulation module is linked with the pulse generator and configured to cause the pulse generator to terminate the pulse when the level of electric energy is determined to be below the threshold electric energy; and a switch in communicative connection with the pulse generator, the switch being configured to open when the regulation module causes termination of the pulse.
Clause 7. The circuit of any of clauses 1-6, further comprising a pulse generator, wherein the pulse generator is configured to pause between pulses for a predetermined duration, the predetermined duration being selected so as to allow the electric energy stored in the storage element to reach an upper energy threshold, based on the electric current provided by the power source.
Clause 8. The circuit of any of clauses 1-7, further comprising a pulse generator configured to generate the pulse, the pulse having a pulse duration shorter than a discharge duration of the storage element when discharging the electric energy at the predetermined current threshold of the light emitter.
Clause 9. The circuit of any of clauses 1-8, wherein the circuit has a length, X, and a width, Y, and a surface area, X*Y, wherein the surface area is less than 0.09 mm².
Clause 10. The circuit of any of clauses 1-9, wherein the peak power is 1000 times greater than the average power.
Clause 11. The circuit of any of clauses 1-9, wherein the peak power is 10000 times greater than the average power.
Clause 12. The circuit of any of clauses 1-11, wherein the storage element comprises a battery.
Clause 13. The circuit of any of clauses 1-12, wherein an average of a standby electric current between the pulse and a second pulse following the pulse is less than 10⁻⁸ Amperes.
Clause 14. The circuit of any of clauses 1-13, wherein the average power available from the power source is less than 10⁻⁶ Watts.
Clause 15. The circuit of any of clauses 1-14, wherein the light emitter comprises a vertical-cavity surface emitting laser (VCSEL) and the average power drawn from the storage element to provide the electric energy to the light emitter is less than 10⁻⁷ Watts.
Clause 16. The circuit of clause 15, wherein the regulation module is further configured to enable the VCSEL to emit light based on a voltage across the VCSEL.
Clause 17. The circuit of any of clauses 1-16, wherein an average current through the light emitter when the level is determined to be below the threshold electric energy is less than 1 microamp.
Clause 18. The circuit of any of clauses 1-17, wherein a circuit average power corresponding to the power consumed by the circuit is less than 1 microwatt.
Clause 19. The circuit of any of clauses 1-18, wherein a pulse duration of the pulse is fixed based on predetermined data.
Clause 20. The circuit of any of clauses 1-19, wherein the light emitter is configured to draw electric energy from the storage element as an electric current of less than or equal to 0.7 milliamperes while emitting light at or above the predetermined current threshold.
Clause 21. A method for driving a vertical-cavity surface-emitting laser (VCSEL), comprising: storing electric energy from a photovoltaic cell in a storage device; and providing a pulse, by a pulse generator, to cause the storage device to provide stored electric energy to the VCSEL during the pulse, wherein: the electric energy is provided by the storage device at a predetermined current level of the VCSEL, the predetermined current level corresponding to a current at which an efficiency of the VCSEL in emitting light is greater than or equal to a predetermined efficiency.
Clause 22. The method of clause 21, wherein the circuit uses an average power of less than 10⁻⁶ Watts, and the peak power of the VCSEL pulse is higher than 10⁻⁶ Watts.
Clause 23. The method of any of clauses 21-22, wherein the storage device is configured to receive electric energy and reach the threshold current level in less than 0.1 seconds.
Clause 24. The method of any of clauses 21-23, wherein the pulse generator is further configured to provide the pulse after receiving a command from a regulation module based on a voltage across the VCSEL.
Clause 25. The circuit of any of clauses 21-24, wherein the light emitter comprises a vertical-cavity surface emitting laser (VCSEL) and an average power drawn from the storage device to provide the stored electric energy to the VCSEL is less than 10⁻⁷ Watts.
Clause 26. A circuit for driving a light emitter for an adaptable duration, comprising: a power source configured to store and provide electric energy; a power monitor configured to monitor an available energy from the power source; and a pulse generator configured to generate a pulse for a pulse duration based on the available energy, wherein the pulse duration is determined such that a pulse energy for the pulse duration remains below the available energy throughout the pulse duration, and wherein the pulse energy is configured to cause the light emitter to produce light at a predetermined intensity for each pulse.
Clause 27. The circuit of clause 26, wherein the power source comprises one or more photovoltaic cells configured to collect incident light, and the pulse duration is based on the amount of incident light collected by the one or more photovoltaic cells.
Clause 28. The circuit of any of clauses 26-27, wherein the pulse duration directly correlates to the average power corresponding to the electric energy available from the power source.
Clause 29. A circuit for driving a light emitter with a current source, comprising: a power source configured to store and provide electric energy, wherein the electric energy stored in the power source over a duration corresponds to an available average power; a pulse generator configured to generate a pulse for a pulse period, the pulse period being determined based on a peak power of the pulse, the peak power being greater than the available average power, and the pulse period being less than the duration; a current source element configured to provide a steady current from the power source to the light emitter during the pulse period, wherein the current source element has an operational current greater than to a threshold electric current for the light emitter; and a comparison module configured to determine a voltage across the current source and compare the voltage to the operational voltage threshold, wherein when the voltage is greater than or equal to the operational voltage threshold, the pulse continues; and, when the voltage is lower than the operational voltage threshold, the pulse generator is configured to terminate the pulse.
Clause 30. The circuit of clause 29, wherein the comparison module comprises a comparator configured to compare the voltage across the current source to the operational voltage threshold.
Clause 31. The circuit of clause 30, wherein the comparator comprises a CMOS inverter configured with one or more transistors connected in series, wherein the operational voltage threshold is determined based on the quantity of the one or more transistors of the CMOS inverter.
Clause 32. The circuit of any of clauses 29-31, wherein the current source is configured as a current mirror used to provide a fixed electric current through the light emitter.
Clause 33. The circuit of any of clauses 29-32, wherein the comparison module is configured to operate an SR latch used to control a switch configured to allow or restrict the electric energy from reaching the light emitter.
Clause 34. The circuit of any of clauses 29-33, wherein the power source comprises one or more photovoltaic cells configured to receive incident light, and when the brightness of incident light decreases, the steady current from the current source is configured to increase.
Clause 35. The circuit of clause 32, wherein the current mirror is configured to connect to a switch in series and the comparison module is configured to use the switch to terminate electric current from reaching the light emitter when the voltage across the current source is lower than the operational voltage threshold.
Clause 36. The circuit of any of clauses 29-35, wherein the comparison module further comprises a comparator connected to a set-reset latch and logic gates configured to initiate the pulse by a rising edge of a control input voltage, and terminate the pulse when the voltage across the current source is less than the operational voltage threshold.
Clause 37. A circuit for driving a light emitter with a voltage offset, the circuit comprising: a power source configured to store and provide electric energy at a power voltage; a voltage bias element configured to provide a bias voltage in series with the power voltage; and a comparison circuit configured to compare the voltage from the voltage bias element to the voltage corresponding to a light emitter voltage threshold, wherein the comparison circuit is further configured to enable the power source to provide the electric energy to the light emitter in a pulse for a pulse period based on a peak power of the pulse, the peak power being greater than an available average power corresponding to the energy stored in the power source over a duration greater than the pulse period, when the voltage from the voltage bias element is greater than or equal to the light emitter voltage threshold, and the comparison circuit is further configured to restrict the power source from providing the electric energy to the light emitter, when the voltage from the voltage bias element is less than the light emitter voltage threshold.
Clause 38. The circuit of clause 37, wherein the comparison circuit comprises a comparator comprising a CMOS inverter configured with one or more transistors connected in series, wherein the bias voltage is determined based on the quantity of the one or more transistors in the CMOS inverter.
Clause 39. The circuit of any of clauses 37-38, wherein the bias voltage corresponds to a threshold electric energy corresponding to a minimum voltage for the light emitter to emit light, and over which the brightness of the light emitted from the light emitter begins to rise monotonically.
Clause 40. The circuit of clause 39, wherein the light emitter comprises a vertical-cavity surface-emitting laser (VCSEL).
Clause 41. The circuit of any of clauses 37-40, wherein the comparison circuit is configured to operate a set-reset latch used to control a switch configured to allow or restrict the electric energy from reaching the light emitter.
Clause 42. The circuit of any of clauses 37-41, wherein the power source comprises one or more photovoltaic cells configured to receive incident light, and the bias voltage is adjustable based on the brightness of incident light, wherein the bias voltage is adjusted to be inversely proportional to the brightness of incident light.
Clause 43. The circuit of any of clauses 37-42, wherein the bias voltage is adjustable based on the average power corresponding to the electric energy available from the power source.
Clause 44. The circuit of any of clauses 37-43, wherein the comparison circuit is further configured to restrict the power source from providing the electric energy by communicating with a switch configured to operate in response to the pulse.
Clause 45. The circuit of any of clauses 37-44, wherein the comparison circuit further comprises a comparator connected to an SR latch and one or more logic gates configured to operate with the pulse by a rising edge of a control input voltage, and terminate the pulse when the electric energy from the voltage bias element is less than the threshold electric energy.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

This disclosure employs open-ended permissive language, indicating for example, that some embodiments “may” employ, involve, or include specific features. The use of the term “may”, and other open-ended terminology is intended to indicate that although not every embodiment may employ the specific disclosed feature, at least one embodiment employs the specific disclosed feature.

Various terms used in the specification and claims may be defined or summarized differently when discussed in connection with differing disclosed embodiments. It is to be understood that the definitions, summaries and explanations of terminology in each instance apply to all instances, even when not repeated, unless the transitive definition, explanation or summary would result in inoperability of an embodiment.

Throughout the description, including the claims, the term “comprising a” should be understood as being synonymous with “comprising at least one” unless otherwise stated. In addition, any range set forth in the description, including the claims should be understood as including its end value(s) unless otherwise stated. Specific values for described elements should be understood to be within accepted manufacturing or industry tolerances known to one of skill in the art, and any use of the terms “substantially” and/or “approximately” and/or “generally” should be understood to mean falling within such accepted tolerances.

What is claimed is:

1. An optically powered electronic circuit to drive a light emitter at low power, the optically powered electronic circuit comprising:
a storage element configured to store electric energy;
a power source configured to generate electric current and provide the electric current to the storage element for storage as electric energy; and
a regulation module configured to determine a level of electric energy stored in the storage element and compare the level of electric energy to a threshold electric energy corresponding to a predetermined current threshold of the light emitter, wherein:
the regulation module is configured such that:
when the level is determined to be greater than or equal to the threshold electric energy and information is to be transmitted by the optically powered electronic circuit, the electric energy stored in the storage element is provided to the light emitter in a pulse, and
when the level is determined to be below the threshold electric energy, the electric energy stored in the storage element is restricted from reaching the light emitter,
and wherein a peak power of the pulse is greater than an average power available from the power source.

2. The optically powered electronic circuit of claim 1, wherein the storage element comprises at least one capacitor configured to provide electric energy.

3. The optically powered electronic circuit of claim 1, wherein the power source is further configured to transduce incident light to generate the electric current.

4. The optically powered electronic circuit of claim 3, wherein the power source comprises a photovoltaic cell stack connected in series and configured to provide the electric current in proportion to an amount of incident light collected by the photovoltaic cell stack.

5. The optically powered electronic circuit of claim 4, wherein the power source further comprises a second photovoltaic cell stack connected in parallel with the photovoltaic cell stack and configured to provide electric energy in proportion to the amount of incident light collected by the photovoltaic cell stack.

6. The optically powered electronic circuit of claim 1, further comprising:
a pulse generator configured to generate the pulse,
wherein the regulation module is linked with the pulse generator and configured to cause the pulse generator to terminate the pulse when the level of electric energy is determined to be below the threshold electric energy; and
a switch in communicative connection with the pulse generator, the switch being configured to open when the regulation module causes termination of the pulse.

7. The optically powered electronic circuit of claim 1, further comprising a pulse generator, wherein the pulse generator is configured to pause between pulses for a predetermined duration, the predetermined duration being selected so as to allow the electric energy stored in the storage element to reach an upper energy threshold, based on the electric current provided by the power source.

8. The optically powered electronic circuit of claim 1, further comprising a pulse generator configured to generate the pulse, the pulse having a pulse duration shorter than a discharge duration of the storage element when discharging the electric energy at the predetermined current threshold of the light emitter.

9. The optically powered electronic circuit of claim 1, wherein the optically powered electronic circuit has a length, X, and a width, Y, and a surface area, X*Y, wherein the surface area is less than 0.09 mm².

10. The optically powered electronic circuit of claim 1, wherein the peak power is 1000 times greater than the average power.

11. The optically powered electronic circuit of claim 10, wherein the peak power is 10000 times greater than the average power.

12. The optically powered electronic circuit of claim 1, wherein the storage element comprises a battery.

13. The optically powered electronic circuit of claim 1, wherein an average of a standby electric current between the pulse and a second pulse following the pulse is less than 10⁻⁸ Amperes.

14. The optically powered electronic circuit of claim 1, wherein the average power available from the power source is less than 10⁻⁶ Watts.

15. The optically powered electronic circuit of claim 1, wherein the light emitter comprises a vertical-cavity surface emitting laser (VCSEL) and the average power drawn from the storage element to provide the electric energy to the light emitter is less than 10⁻⁷ Watts.

16. The optically powered electronic circuit of claim 15, wherein the regulation module is further configured to enable the VCSEL to emit light based on a voltage across the VCSEL.

17. The optically powered electronic circuit of claim 1, wherein an average current through the light emitter when the level is determined to be below the threshold electric energy is less than 1 microamp.

18. The optically powered electronic circuit of claim 1, wherein a circuit average power corresponding to power consumed by the optically powered electronic circuit is less than 1 microwatt.

19. The optically powered electronic circuit of claim 1, wherein a pulse duration of the pulse is fixed based on predetermined data.

20. The optically powered electronic circuit of claim 1, wherein the light emitter is configured to draw electric energy from the storage element as an electric current of less than or equal to 0.7 milliamperes while emitting light at or above the predetermined current threshold.
